(19) United States
(12) Patent Application Publication
(10) Pub. No.: US 2022/0328536 A1
(43) Pub. Date: Oct. 13, 2022

(54) IMAGING DEVICE, PRODUCTION METHOD, AND ELECTRONIC APPARATUS

(71) Applicant: SONY SEMICONDUCTOR SOLUTIONS CORPORATION, Kanagawa (JP)

(72) Inventors: Hironobu FUKUI, Kanagawa (JP); Shouichirou SHIRAISHI, Kumamoto (JP)

(73) Assignee: SONY SEMICONDUCTOR SOLUTIONS CORPORATION, Kanagawa (JP)

(21) Appl. No.: 17/634,328

(22) PCT Filed: Aug. 17, 2020
(86) PCT No.: PCT/JP2020/030950

§ 371 Date: Feb. 10, 2022

(30) Foreign Application Priority Data
Aug. 27, 2019 (JP) 2019-154343

(51) Int. Cl. H01L 27/146

(52) U.S. Cl. CPC H01L 27/1463; H01L 27/14603; H01L 27/14685; H01L 27/14621; H01L 27/14623; H01L 27/14627

(57) ABSTRACT

An imaging device (11) includes a plurality of photoelectric converters, a separation portion (22, 23), and a plurality of elements. The photoelectric converter is provided to a semiconductor substrate. The separation portion is provided between pixels (21Gr, 21Gb, 21R, 21B) each including the photoelectric converter, the separation portion extending up to a specified depth from a light entrance surface of the semiconductor substrate, the light entrance surface being on a side on which light enters the semiconductor substrate. The element is provided on an element forming surface that is on a side opposite to the side of the light entrance surface. A first depth is deeper than a second depth, the first depth being a depth of the separation portion (22) provided in a region in which the element is provided, the second depth being a depth of the separation portion (23) provided in a region in which the element is not provided.

### TECHNICAL FIELD

The present disclosure relates to an imaging device, a production method, and an electronic apparatus, and relates to, in particular, an imaging device, a production method, and an electronic apparatus that make it possible to further improve an image quality.

### CROSS REFERENCE TO RELATED APPLICATIONS

This application claims the benefit of Japanese Priority Patent Application JP 2019-154343 filed Aug. 27, 2019, the entire contents of which are incorporated herein by reference.

### BACKGROUND ART

In the past, a layout and a structure in which photodiodes are separated from one another for each pixel using a trench formed by physically engraving a semiconductor substrate from the side of a light entrance surface, have been adopted in a backside-illuminated complementary metal-oxide semiconductor (CMOS) image sensor. In general, trenches are provided in the form of a lattice in order to perform engraving between pixels without a space.

On the other hand, as disclosed in Patent Literature 1, an imaging device has been proposed that has a configuration in which a separation portion is provided to a trench formed between adjacent pixels in order to block light incident from an oblique direction.

### CITATION LIST

### Patent Literature

PTL 1: Japanese Patent Application Laid-open No. 2013-243324

### SUMMARY OF INVENTION

### Technical Problem

When the volume of a photodiode is increased in an imaging device in order to increase the quantity of saturation signals (Qs), there is a need to increase charge shielding (resistance to blooming) between adjacent pixels in order to prevent the decrease in an image quality due to charge leakage into the adjacent pixel. Further, in a backside-illuminated CMOS image sensor having a trench structure in which a trench does not pass through a semiconductor substrate, a trench is formed from the side of a light entrance surface of a semiconductor substrate, and a transistor for driving a pixel is arranged on a surface situated opposite to the light entrance surface. In such a structure, a configuration in which pixels are electrically separated from one another by injecting impurities, is adopted in a region in which a trench is not provided, since it is necessary to form a trench such that the trench is situated a certain distance away from a surface on which a transistor is arranged.

However, in the configuration in which pixels are electrically separated from one another using impurities, charge shielding is relatively lower than that of the configuration in which pixels are physically separated from one another using a trench, and this may result in restrictions on increasing the quantity of saturation signals of a photodiode. Further, since color mixture (crosstalk) of light is likely to occur in a region in which a trench is not provided, the decrease in an image quality may occur due to the color mixture of light.

Thus, the image quality is expected to be improved by increasing the quantity of saturation signals of a photodiode and improving charge shielding between adjacent pixels at the same time, and by preventing the occurrence of color mixture.

The present disclosure has been made in view of the circumstances described above and achieves a further improvement in an image quality.

### Solution to Problem

An imaging device according to an embodiment of the present disclosure includes a photoelectric converter that is provided to a semiconductor substrate, the imaging device including a plurality of the photoelectric converters; a separation portion that is provided between pixels each including the photoelectric converter, the separation portion extending up to a specified depth from a light entrance surface of the semiconductor substrate, the light entrance surface being on a side on which light enters the semiconductor substrate; and an element that is provided on an element forming surface that is on a side opposite to the side of the light entrance surface, the imaging device including a plurality of the elements, in which a first depth is deeper than a second depth, the first depth being a depth of the separation portion provided in a region in which the element is provided, the second depth being a depth of the separation portion provided in a region in which the element is not provided.

A method for producing an imaging device according to an embodiment of the present disclosure includes forming a photoelectric converter on a semiconductor substrate, in which a plurality of the photoelectric converters is formed on the semiconductor substrate; forming a separation portion between pixels each including the photoelectric converter, the separation portion extending up to a specified depth from a light entrance surface of the semiconductor substrate, the light entrance surface being on a side on which light enters the semiconductor substrate; and forming an element on an element forming surface that is on a side opposite to the side of the light entrance surface, in which a plurality of the elements is formed on the element forming surface, in which a first depth is deeper than a second depth, the first depth being a depth of the separation portion provided in a region in which the element is provided, the second depth being a depth of the separation portion provided in a region in which the element is not provided.

An electronic apparatus according to an embodiment of the present disclosure includes an imaging device that includes a photoelectric converter that is provided to a semiconductor substrate, the imaging device including a plurality of the photoelectric converters; a separation portion that is provided between pixels each including the photoelectric converter, the separation portion extending up to a specified depth from a light entrance surface of the semiconductor substrate, the light entrance surface being on a side on which light enters the semiconductor substrate; and an element that is provided on an element forming surface that is on a side opposite to the side of the light entrance surface, the imaging device including a plurality of the elements, in which a first depth is deeper than a second depth, the first depth being a depth of the separation portion provided in a region in which the element is provided, the second depth being a depth of the separation portion provided in a region in which the element is not provided.

According to an embodiment of the present disclosure, a photoelectric converter is provided to a semiconductor substrate, in which a plurality of the photoelectric converters is provided to the semiconductor substrate; a separation portion is provided between pixels each including the photoelectric converter, the separation portion extending up to a specified depth from a light entrance surface of the semiconductor substrate, the light entrance surface being on a side on which light enters the semiconductor substrate; and an element is provided on an element forming surface that is on a side opposite to the side of the light entrance surface, in which a plurality of the elements is provided on the element forming surface. Further, a first depth is deeper than a second depth, the first depth being a depth of the separation portion provided in a region in which the element is provided, the second depth being a depth of the separation portion provided in a region in which the element is not provided.

### BRIEF DESCRIPTION OF DRAWINGS

FIG. 1 illustrates a configurative example of a first embodiment of an imaging device using the present technology.

FIG. 2 illustrates an example of a cross-sectional structure of the imaging device.

FIG. 3 illustrates an example of a cross-sectional structure of the imaging device.

FIG. 4 is a diagram describing a relationship between charge leakage and a quantity of saturation signals.

FIG. 5 is a diagram describing spectral characteristics.

FIG. 6 illustrates an example of a configuration of a pixel in the case of the image height center.

FIG. 7 illustrates an example of a configuration of a pixel in the case of the image height −80%.

FIG. 8 illustrates an example of a configuration of a pixel in the case of the image height +80%.

FIGS. 9A and 9B illustrate configurative examples of a second embodiment of an imaging device using the present technology.

FIG. 10 illustrates a configurative example of a third embodiment of an imaging device using the present technology.

FIG. 11 illustrates a first modification of the third embodiment.

FIG. 12 illustrates a second modification of the third embodiment.

FIG. 13 illustrates a third modification of the third embodiment.

FIGS. 14A and 14B illustrate examples of a cross-sectional structure of the imaging device.

FIG. 15 is a diagram describing a method for producing the imaging device.

FIG. 16 is a diagram describing the method for producing the imaging device.

FIG. 17 is a block diagram illustrating a configurative example of an image-capturing device.

FIG. 18 illustrates a usage example of using an image sensor.

### DESCRIPTION OF EMBODIMENTS

Specific embodiments using the present technology will now be described below in detail with reference to the drawings.

First Configurative Example of Imaging Device

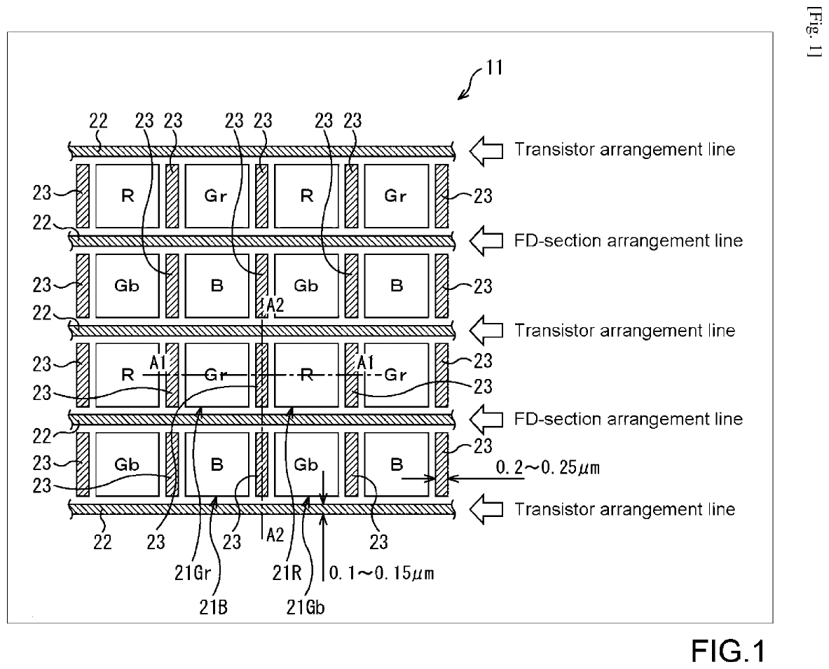

A configurative example of a first embodiment of an imaging device using the present technology is described with reference to FIGS. 1 to 8.

FIG. 1 illustrates a layout of an imaging device 11 as viewed in a planar manner.

As illustrated in FIG. 1, in the imaging device 11, a plurality of pixels 21 is arranged in an array in a row direction and in a column direction, in which a pixel separation portion 22 and a pixel separation portion 23 are provided that separate adjacent pixels 21.

Further, the imaging device 11 is configured such that a red pixel 21R, a green pixel 21Gr, a blue pixel 21B, and a green pixel Gb are provided in Bayer arrangement with two pixels in a longitudinal direction and two pixels in a transverse direction. Note that the red pixel 21R, the green pixel 21Gr, the blue pixel 21B, and, the green pixel Gb will each be hereinafter simply referred to as the pixel 21 when there is no need to distinguish among those pixels.

The pixel separation portion 22 is provided to extend in the row direction such that the pixel separation portion 22 is provided continuously with respect to a plurality of pixels 21 for each row of the pixel 21. For example, the pixel separation portion 22 is formed to have a length corresponding to one line of the pixels 21.

The pixel separation portion 23 is provided to extend in the column direction such that the pixel separation portions 23 are each provided with respect to one pixel 21 in a discontinuous manner for each column of the pixel 21. For example, the pixel separation portion 23 is formed for each pixel 21 such that the length of the pixel separation portion 23 in the column direction is substantially the same as (or not greater than) the length of the side of the pixel 21.

As described above, the imaging device 11 has a layout in which the pixel separation portion 22 and the pixel separation portion 23 do not intersect each other, and a space is provided that makes the pixel separation portion 22 and the pixel separation portion 23 discontinuous.

For example, in a general imaging device, pixel separation portions are provided in a lattice pattern, and an intersection portion is provided, the intersection portion being a portion at which a pixel separation portion extending in a row direction and a pixel separation portion extending in a column direction intersect each other. For this reason, when etching is performed to form a pixel separation portion, the intersection portion will be engraved most deeply due to the micro-loading effects. Thus, in the pixel separation portion, it is not possible to engrave a region other than the intersection portion more deeply than the intersection portion, and thus charge leakage and color mixture of light may occur in the portion other than the intersection portion.

On the other hand, in the imaging device 11, the pixel separation portion 22 extending in the row direction and the pixel separation portion 23 extending in the column direction are provided in a pattern in which the pixel separation portion 22 and the pixel separation portion 23 have no intersection portion. Thus, in the imaging device 11, the above-described phenomenon in which an intersection portion is engraved most deeply does not occur, and thus it is possible to form the pixel separation portion 22 and the pixel separation portion 23 respectively engraved up to desired depths. Thus, the imaging device 11 makes it possible to prevent the occurrence of charge leakage and color mixture of light between adjacent pixels 21 by the pixel separation portion 22 and the pixel separation portion 23 being deeply engraved.

Here, the pixel separation portion 22 and the pixel separation portion 23 are each formed to extend up to a depth depending on the length as viewed in a planar manner due to the micro-loading effects exhibited when etching is performed.

As illustrated in FIG. 1, for example, the pixel separation portion 22 has a width in a range of 0.1 to 0.15 μm, and the pixel separation portion 23 has a width in a range of 0.2 to 0.25 μm, in which the widths of the pixel separation portion 22 and the pixel separation portion 23 are set such that the pixel separation portion 23 is larger in width than the pixel separation portion 22 with certainty. In other words, the width of the pixel separation portion 22 is set to be smaller than the width of the pixel separation portion 23. Thus, when the pixel separation portion 22 and the pixel separation portion 23 are collectively processed, the pixel separation portion 23 having a larger width is formed to have a deeper depth than the depth of the pixel separation portion 22 having a smaller width, due to an impact of the micro-loading effects exhibited when etching is performed.

Further, as illustrated in the figure, a transistor arrangement line and an FD-section arrangement line are alternately provided between the pixels 21 in the row direction, the transistor arrangement line being a line in which a transistor is arranged that drives the pixel 21, the FD-section arrangement line being a line in which an FD section is arranged that temporarily accumulates therein charge transferred from the pixel 21. Thus, in the imaging device 11, the pixel separation portion 22 formed to extend up to a shallow depth is arranged in the transistor arrangement line and the FD-section arrangement line, and the pixel separation portion 23 formed to extend up to a deep depth is arranged in a region in which a transistor or an FD section is not arranged.

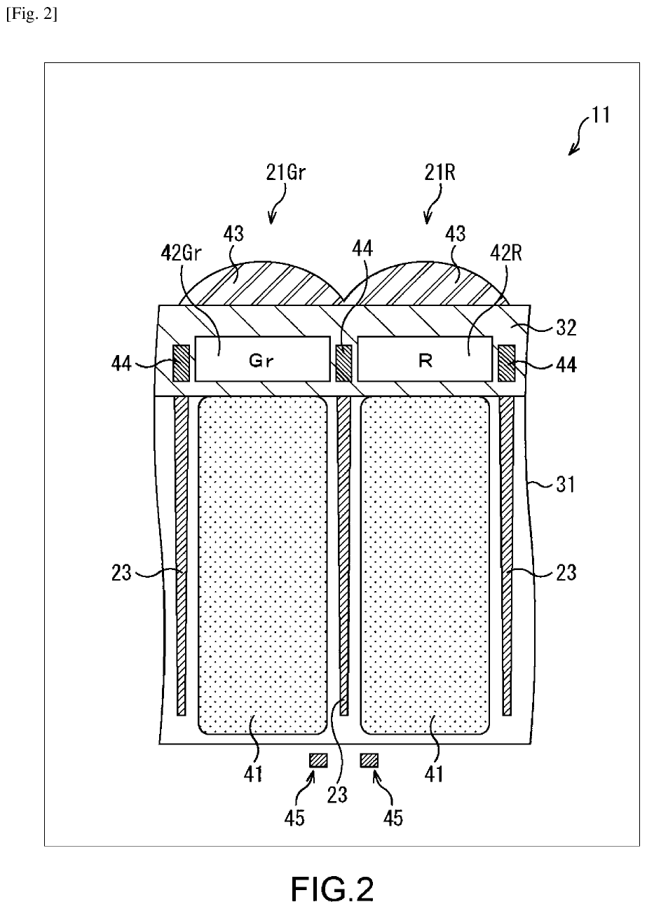

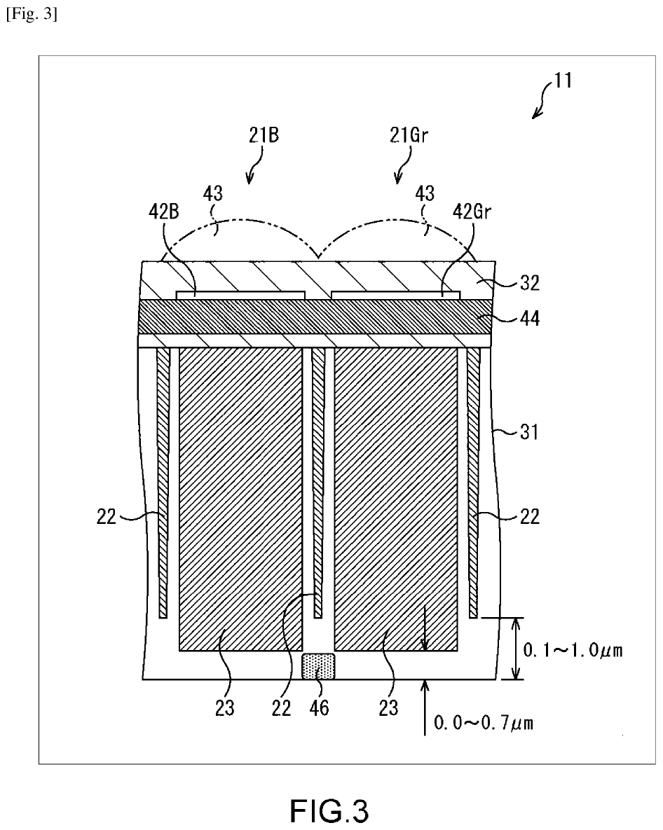

Cross-sectional structures of the imaging device 11 are described with reference with FIGS. 2 and 3.

FIG. 2 illustrates a configurative example of the imaging device 11 in a cross section taken along the dot-dash line A1-A1 of FIG. 1, and FIG. 3 illustrates a configurative example of the imaging device 11 in a cross section taken along the dot-dash line A2-A2 of FIG. 1.

For example, in the imaging device 11, an insulation layer 32 is stacked on a light entrance surface of a semiconductor substrate 31, the insulation layer 32 being formed of an insulating oxide film, the semiconductor substrate 31 being made of monocrystalline silicon, and a wiring layer (not illustrated) is stacked on a surface (hereinafter referred to as an element forming surface) of the semiconductor substrate 31 that faces the opposite direction of the light entrance surface.

Further, in the imaging device 11, the photodiode 41 that is a photoelectric converter is formed on the semiconductor substrate 31 for each pixel 21, and an on-chip lens 43 that collects light onto the photodiode 41 is stacked on the insulation layer 32. Furthermore, a color filter 42R through which red light is transmitted is arranged on the insulation layer 32 of the red pixel 21R, a color filter 42Gr and a color filter 42Gb through which green light is transmitted are respectively arranged on the insulation layer 32 of the green pixel 21G and the insulation layer 32 of the green pixel 21Gb, and a color filter 42B through which blue light is transmitted is arranged on the insulation layer 32 of the blue pixel 21B. Moreover, an inter-pixel light shielding film 44 that is made of light shielding metal is provided to the insulation layer 32 between a plurality of pixels 21 arranged in an array such that the plurality of pixels 21 is provided in the form of a lattice.

Further, as illustrated in FIG. 2, a transistor 45 (such as a transfer transistor for transferring charge accumulated in the pixel 21) that drives the pixel 21 is arranged to be stacked on the element forming surface of the semiconductor substrate 31 through an insulation film (not illustrated). Furthermore, as illustrated in FIG. 3, an FD section 46 that temporarily accumulates therein the charge transferred from the pixel 21 is formed to be exposed on the element forming surface of the semiconductor substrate 31.

Here, as described with reference to FIG. 1, the transistor 45 is arranged along the transistor arrangement line, and the FD section 46 is arranged along the FD-section arrangement line.

Thus, the pixel separation portion 22 arranged in the row direction is formed by performing engraving from the side of the light entrance surface of the semiconductor substrate 31 up to a depth at which elements, such as the transistor 45 and the FD section 46, that are formed on the element forming surface of the semiconductor substrate 31 are not reached. On the other hand, the pixel separation portion 23 arranged in the column direction can be formed by performing engraving deeper than the pixel separation portion 22 regardless of the transistor 45 and the FD section 46.

For example, as illustrated in FIG. 3, the pixel separation portion 22 is formed up to a depth in which a space (an amount of remaining silicon) between the tip of the pixel separation portion 22 and the element forming surface of the semiconductor substrate 31 is in a range of 0.1 to 1.0 μm. Likewise, the pixel separation portion 23 is formed up to a depth in which a space between the tip of the pixel separation portion 23 and the element forming surface of the semiconductor substrate 31 is in a range of 0.0 to 0.7 μ, and may be formed to pass through the semiconductor substrate 31. Then, the pixel separation portion 22 and the pixel separation portion 23 are formed such that the pixel separation portion 23 is deeper in depth than the pixel separation portion 22 with certainty.

The imaging device 11 having such a configuration in which the pixels 21 are physically separated from one another using the pixel separation portion 22 and the pixel separation portion 23, makes it possible to improve charge shielding between adjacent pixels 21, compared to, for example, a configuration in which pixels are electrically separated from one another by injecting impurities. Accordingly, in the imaging device 11, it is possible to, for example, increase the volume of the photodiode 41, and this results in being able to increase the quantity of saturation signals and to increase a dynamic range.

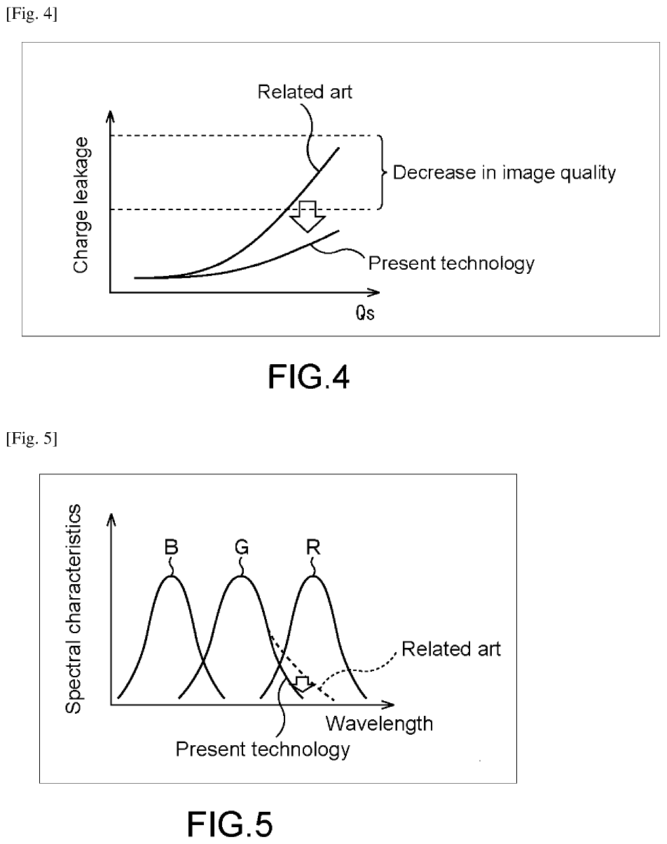

For example, as illustrated in FIG. 4, when the quantity of saturation signals (Qs) is increased, there is an increase in charge leakage, and, in related art, charge may be leaked away until a decrease in an image quality is caused when charge shielding is low. On the other hand, the imaging device 11 using the present technology makes it possible to increase charge shielding. This results in being able to prevent the occurrence of charge leakage in order to not cause a decrease in an image quality even if, as in the related art, the quantity of saturation signals is increased until a decrease in an image quality is caused.

Further, the imaging device 11 makes it possible to prevent the occurrence of color mixture of light between adjacent pixels 21 by the pixel separation portion 22 and the pixel separation portion 23 each being formed to extend up to a deep depth. Consequently, as illustrated in FIG. 5, the imaging device 11 using the present technology makes it possible to obtain more excellent spectral characteristics than the related art.

Thus, the imaging device 11 makes it possible to improve the performance in pixel separation performed using the pixel separation portion 22 and the pixel separation portion 23. This results in being able to perform imaging with an increased dynamic range and with more excellent spectral characteristics and to improve a quality of an image obtained by the imaging.

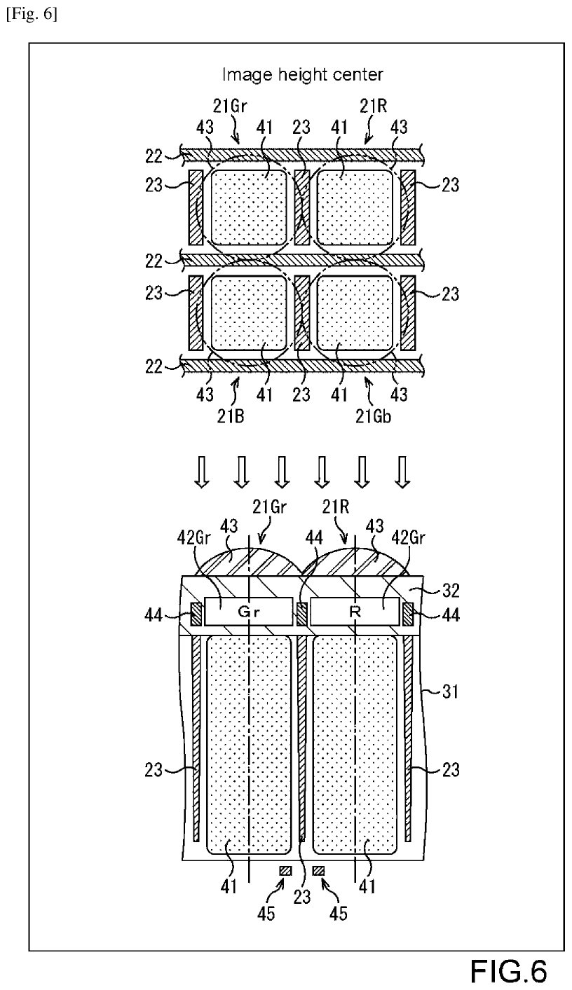

Further, in the imaging device 11, it is possible to perform pupil correction by adjusting the position for arranging the pixel separation portion 23 according to the image height. Thus, this makes it possible to, for example, prevent the occurrence of color mixture of light at an end of an angle of view. The adjustment of the position for arranging the pixel separation portion 23 depending on the image height is described with reference to FIGS. 6 to 8.

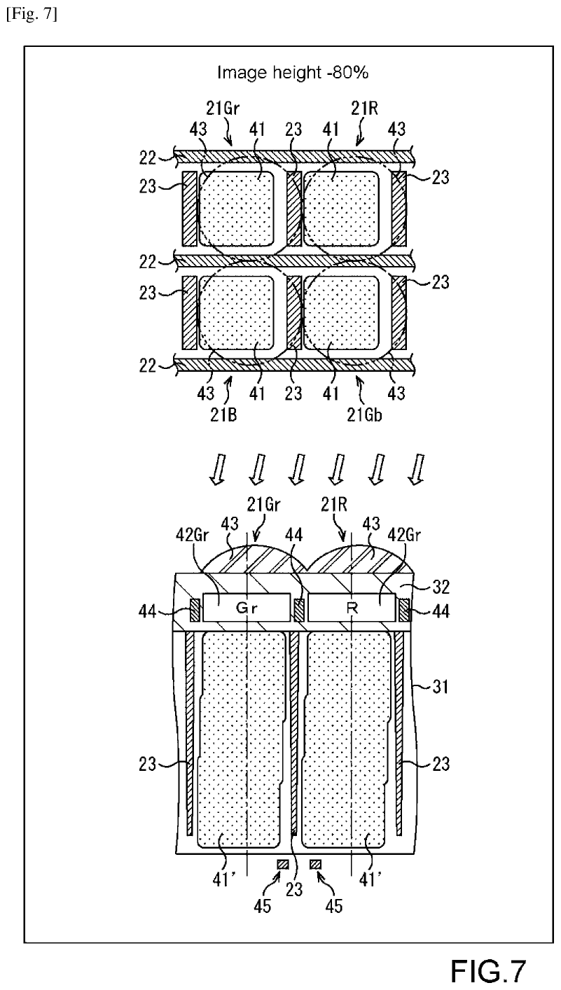

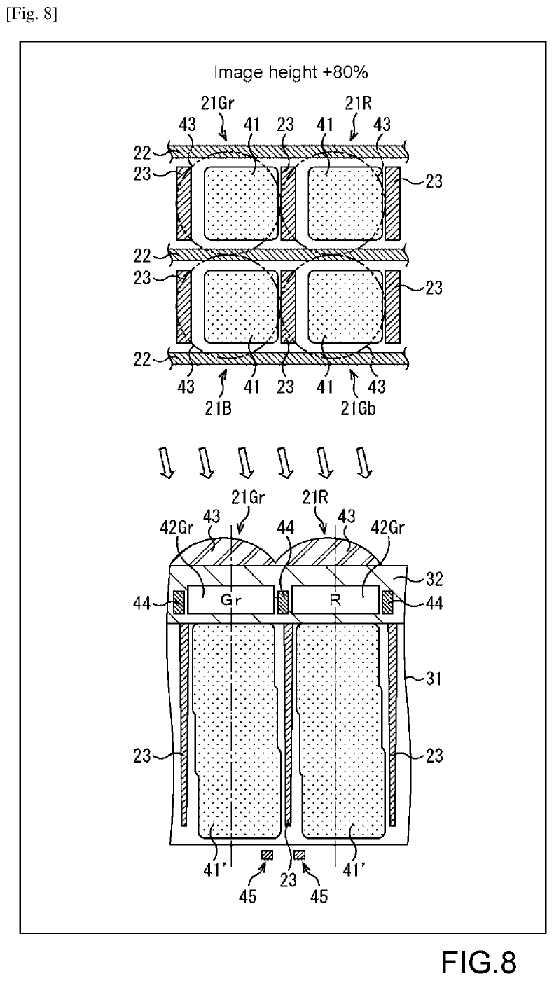

FIG. 6 illustrates a planar layout and a cross-sectional configuration in the case of the image height center, FIG. 7 illustrates a planar layout and a cross-sectional configuration in the case of the image height −80%, and FIG. 8 illustrates a planar layout and a cross-sectional configuration in the case of the image height +80%.

As illustrated in FIG. 6, in the case of the image height center, light enters in a direction vertical to the light entrance surface, and the pixel separation portion 23 is equally spaced relative to the center of the pixel 21 represented by a dot-dash line. Further, the on-chip lens 43 is arranged such that the center of the on-chip lens 43 coincides with the center of the pixel 21.

As illustrated in FIG. 7, in the case of the image height −80%, light enters in a direction oblique to the light entrance surface from the center to the outside of the imaging device 11. Then, the position for arranging the pixel separation portion 23 is adjusted such that the pixel separation portion 23 is situated close to the center of the pixel 21 on the side of the center of the imaging device 11, and the pixel separation portion 23 is situated away from the center of the pixel 21 outside of the imaging device 11 (moved to the left in the figure). Further, the position for arranging the on-chip lens 43 is adjusted such that the center of the on-chip lens 43 is arranged at a position closer to the side of the center of the imaging device 11 than the center of the pixel 21 (moved to the right in the figure).

As illustrated in FIG. 8, in the case of the image height +80%, light enters in a direction oblique to the light entrance surface from the center to the outside of the imaging device 11. Then, the position for arranging the pixel separation portion 23 is adjusted such that the pixel separation portion 23 is situated close to the center of the pixel 21 on the side of the center of the imaging device 11, and the pixel separation portion 23 is situated away from the center of the pixel 21 outside of the imaging device 11 (moved to the right in the figure). Further, the position for arranging the on-chip lens 43 is adjusted such that the center of the on-chip lens 43 is arranged at a position closer to the side of the center of the imaging device 11 than the center of the pixel 21 (moved to the left in the figure).

Note that, in the imaging device 11, the shape of the photodiode 41 may also be adjusted according to the image height. For example, as illustrated in FIG. 6, in the case of the image height center, the photodiode 41 is formed into a shape in parallel with a direction vertical to the semiconductor substrate 31. On the other hand, in the case of the image height −80% in FIG. 7 and in the case of the image height +80% in FIG. 8, a photodiode 41′ is formed into a shape getting closer to the outside of the imaging device 11 toward the depth direction from the light entrance surface, such that the photodiode 41′ has a shape oblique to the direction vertical to the semiconductor substrate 31. For example, it is possible to form the photodiode 41′ having an oblique shape by moving the position for injecting impurities at the time of forming the photodiode 41′ to the outside according to the depth direction of injecting impurities.

As described above, in the imaging device 11, it is possible to perform pupil correction by adjusting the position for arranging the pixel separation portion 23 according to the image height, and to, for example, properly prevent the occurrence of color mixture of light on the side of a high image height. Further, in the imaging device 11, it is also possible to perform pupil correction by adjusting the position for arranging the on-chip lens 43 according to the image height to change the shape of the photodiode 41.

As described above, the imaging device 11 makes it possible to improve the performance in pixel separation performed between the pixels 21 using the pixel separation portion 22 and the pixel separation portion 23. Accordingly, it is possible to further improve an image quality by increasing the quantity of saturation signals of the photodiode 41 and increasing charge shielding between adjacent pixels 21 at the same time, and by preventing the occurrence of color mixture.

Note that, in addition to the configuration illustrated in FIG. 1 in which a transistor and an FD section are arranged in the row direction, a configuration in which a transistor and an FD section are arranged in the column direction may be adopted for the imaging device 11. In this case, the imaging device 11 may have a configuration in which the pixel separation portion 22 is arranged in the column direction and the pixel separation portion 23 is arranged in the row direction, that is, a configuration obtained by rotating the configuration illustrated in FIG. 1 by 90 degrees.

Further, the imaging device 11 may have a configuration in which the pixel separation portion 22 and the pixel separation portion 23 have substantially the same width. In this case, by processing trenches for the pixel separation portion 22 and the pixel separation portion 23 in ways different from each other, the pixel separation portion 22 and the pixel separation portion 23 can be formed such that the pixel separation portion 22 and the pixel separation portion 23 respectively extend up to different depths, that is, such that the pixel separation portion 23 is deeper in depth than the pixel separation portion 22.

Second Configurative Example of Imaging Device

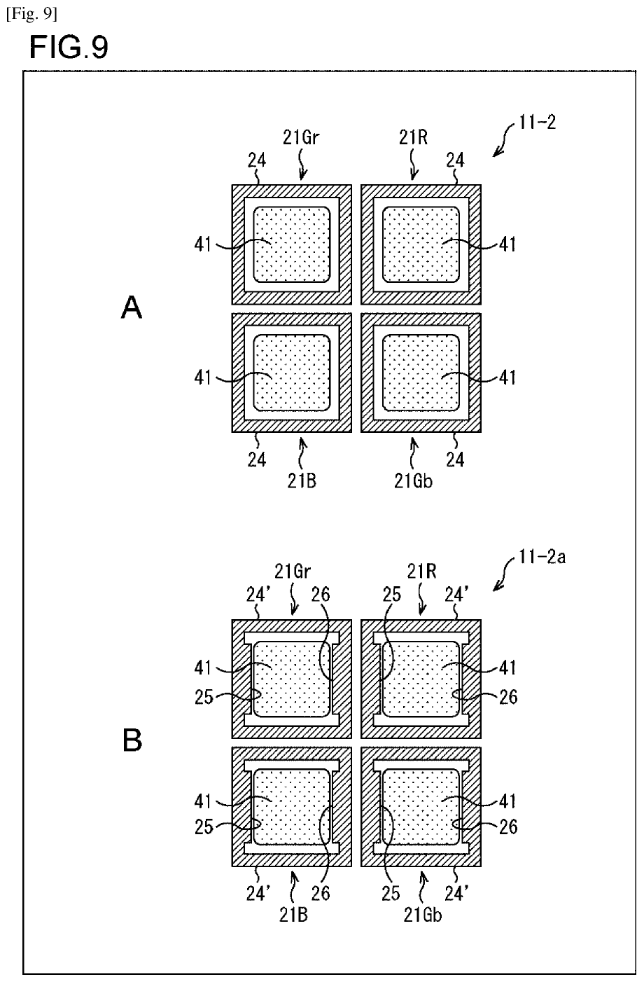

Configurative examples of a second embodiment of an imaging device using the present technology are described with reference to FIGS. 9A and 9B.

FIG. 9A illustrates a planar layout of an imaging device 11-2 according to the second embodiment.

The imaging device 11-2 is similar to the imaging device 11 illustrated in FIG. 1 in that a plurality of pixels 21 is arranged in an array in the row direction and in the column direction.

On the other hand, the imaging device 11-2 is different from the imaging device 11 illustrated in FIG. 1 in that, in each pixel 21, a pixel separation portion 24 that separates adjacent pixels 21 is formed to surround the photodiode 41 on the periphery of the photodiode 41. Further, as in the case of the pixel separation portion 22 and the pixel separation portion 23 of the imaging device 11 illustrated in FIG. 1, the pixel separation portion 24 of the imaging device 11-2 is provided in a pattern in which the pixel separation portions have no intersection portion, as described above.

Thus, in the imaging device 11-2, it is possible to form the pixel separation portion 24 to extend up to a deeper depth, compared to the configuration in which an intersection portion is provided to pixel separation portions. Therefore, the imaging device 11-2 makes it possible to improve the performance in pixel separation performed between the pixels 21 using the pixel separation portion 24.

FIG. 9B illustrates a planar layout of an imaging device 11-2a according to a modification of the second embodiment.

In the imaging device 11-2a, a pixel separation portion 24′ that is formed to surround the photodiode 41 on the periphery of the photodiode 41 is provided in each pixel 21. Further, the pixel separation portion 24′ is intentionally formed such that the width of a desired portion is larger. In the illustrated example, wide portions 25 and 26 are formed on both sides of the pixel separation portion 24′ that extend in the column direction.

For this reason, in the imaging device 11-2a, regions that are situated on both of the sides of the pixel separation portion 24′ and in which the wide portions 25 and 26 are formed, are each formed to extend up to a depth deeper than that of the other regions. For example, in the imaging device 11-2a, the pixel separation portion 24′ is provided such that the wide portions 25 and 26 are formed correspondingly to a portion in which an element such as the transistor 45 (FIG. 2) or the FD section 46 (FIG. 3) is not formed. For this reason, in a portion in which an element such as the transistor 45 (FIG. 2) or the FD section 46 (FIG. 3) is formed, the pixel separation portion 24′ is formed to extend up to a depth at which the element is not reached, and in a portion in which the element is not formed, the pixel separation portion 24′ is formed to extend up to a deeper depth.

Thus, the imaging device 11-2a makes it possible to further improve the performance in pixel separation performed using the pixel separation portion 24′, and to, for example, obtain a more excellent effect of preventing the occurrence of color mixture of light.

As described above, the imaging devices 11-2 and 11-2a respectively make it possible to improve the performance in pixel separation performed between the pixels 21 respectively using the pixel separation portions 24 and 24′, and to further improve an image quality as in the case of the imaging device 11 illustrated in FIG. 1.

Third Configurative Example of Imaging Device

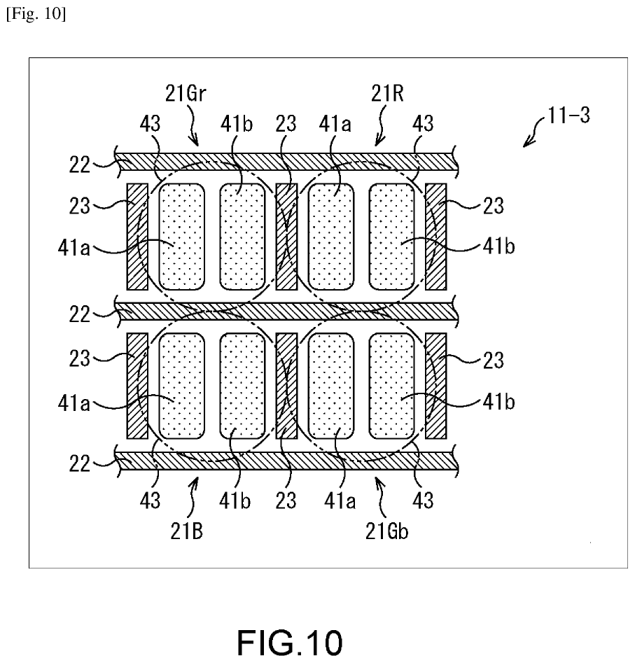

Configurative examples of a third embodiment of an imaging device using the present technology are described with reference to FIGS. 10 to 14.

FIG. 10 illustrates a planar layout of an imaging device 11-3 according to the third embodiment.

The imaging device 11-3 is similar to the imaging device 11 illustrated in FIG. 1 in that a plurality of pixels 21 is arranged in an array in the row direction and in the column direction, in which the pixel separation portion 22 and the pixel separation portion 23 are provided that separate adjacent pixels 21.

On the other hand, the imaging device 11-3 is different from the imaging device 11 illustrated in FIG. 1 in that one pixel 21 includes two photodiodes 41a and 41b. For example, the pixel 21 of the imaging device 11-3 can be used to detect an image-plane phase difference used for autofocus by light collected by one on-chip lens 43 being split to be received by the two photodiodes 41a and 41b.

As described above, the imaging device 11-3 makes it possible to improve the performance in pixel separation performed between the pixels 21 each including the two photodiodes 41a and 41b using the pixel separation portion 22 and the pixel separation portion 23, and to further improve an image quality as in the case of the imaging device 11 illustrated in FIG. 1.

Note that the imaging device 11-3 may include a specified number of photodiodes 41 that is more than one.

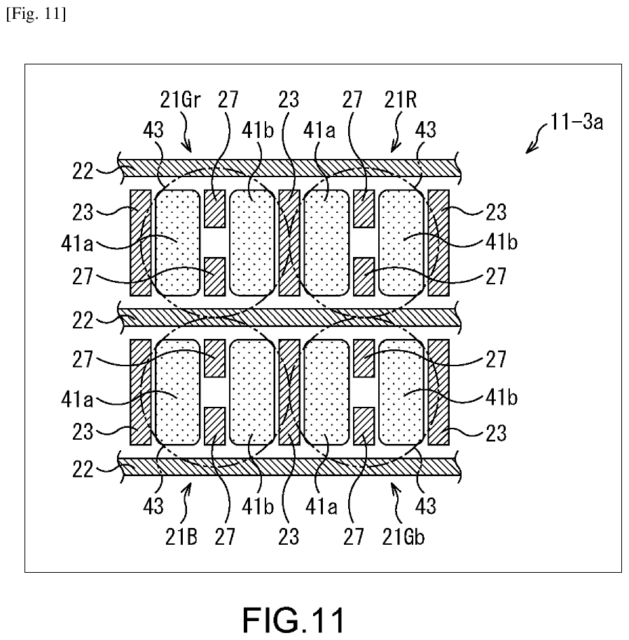

FIG. 11 illustrates a planar layout of an imaging device 11-3a according to a first modification of the third embodiment.

In addition to one pixel 21 including the two photodiodes 41a and 41b as in the case of the imaging device 11-3, the imaging device 11-3a includes pixel separation portions 27 between the photodiodes 41a and 41b. For example, the pixel separation portion 27 is formed to extend up to a depth that is substantially the same as that of the pixel separation portion 23.

In other words, the imaging device 11-3a makes it possible to prevent the occurrence of charge leakage between the photodiodes 41a and 41b by separating the photodiode 41a and the photodiode 41b using the pixel separation portions 27. Accordingly, the imaging device 11-3a makes it possible to, for example, improve the performance in detecting a phase difference.

Further, as illustrated in the figure, in the imaging device 11-3a, the pixel separation portion 27 is formed in a region other than a center portion of the pixel 21 such that the pixel separation portions 27 are spaced from each other across the center portion. Accordingly, the imaging device 11-3a makes it possible to prevent light collected by the on-chip lens 43 from being diffusely reflected off the pixel separation portion 27, although the performance in pixel separation is decreased.

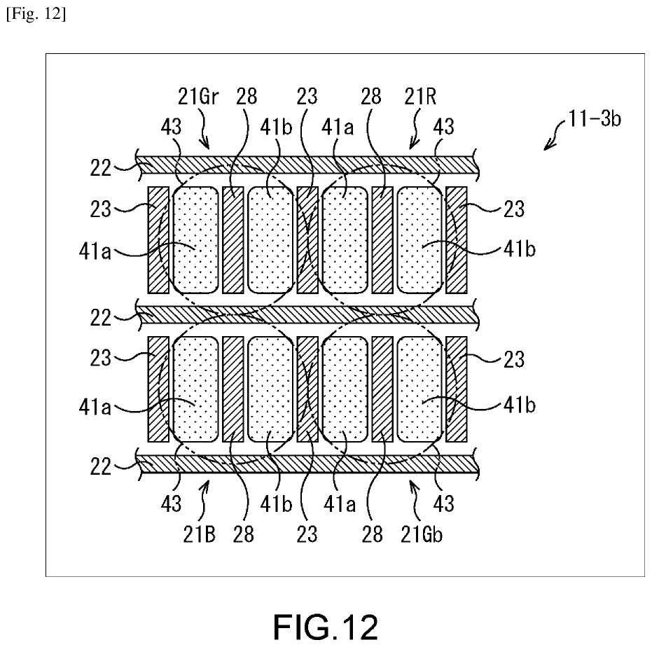

FIG. 12 illustrates a planar layout of an imaging device 11-3b according to a second modification of the third embodiment.

In addition to one pixel 21 including the two photodiodes 41a and 41b as in the case of the imaging device 11-3, the imaging device 11-3b includes a pixel separation portion 28 between the photodiodes 41a and 41b. Further, the pixel separation portion 28 of the imaging device 11-3b is formed to continuously separate the photodiodes 41a and 41b, whereas the pixel separation portion 27 of the imaging device 11-3a is formed such that the pixel separation portions 27 are spaced from each other across the center portion of the pixel 21. For example, the pixel separation portion 28 is formed to extend up to a depth that is substantially the same as that of the pixel separation portion 23.

The imaging device 11-3b having such a configuration makes it possible to further prevent the occurrence of charge leakage between the photodiodes 41a and 41b, and to, for example, further improve the performance in pixel separation, compared to the imaging device 11-3a.

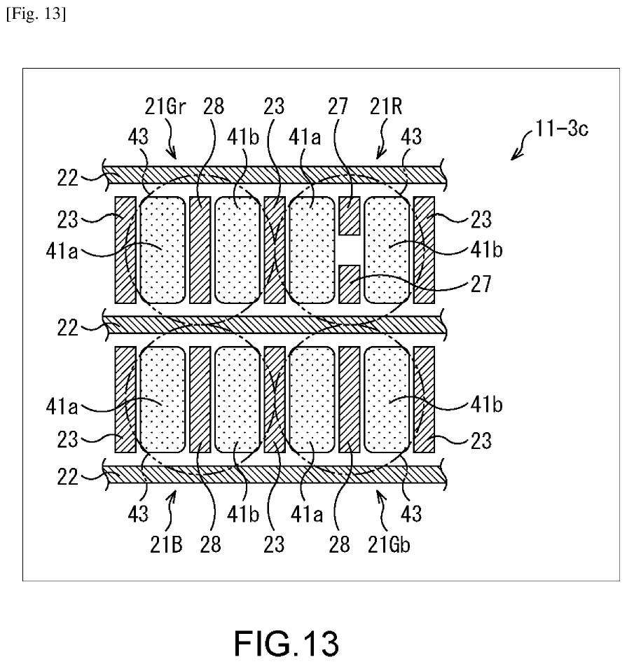

FIG. 13 illustrates a planar layout of an imaging device 11-3c according to a third modification of the third embodiment.

In the imaging device 11-3c, one pixel 21 includes the two photodiodes 41a and 41b, as in the case of the imaging device 11-3. Further, in the imaging device 11-3c, the green pixels 21Gr and 21Gb and the blue pixel 21B each include the pixel separation portion 28, and the red pixel 21R include the pixel separation portions 27 spaced from each other across the center portion of the red pixel 21R. The imaging device 11-3c having such a configuration makes it possible to prevent the occurrence of color mixture of light between adjacent pixels having a wavelength dependence on each other, and, specifically, to prevent the occurrence of color mixture of light with respect to the green pixels 21Gr and 21Gb and the blue pixel 21B, due to light being diffusely reflected off the red pixel 21R, as well as to improve the performance in pixel separation.

Note that a combination of the pixel separation portion 27 and the pixel separation portion 28 to be provided is not limited to the layout illustrated in FIG. 13, and any combination may be used for each pixel 21. Further, as illustrated in FIG. 10, a configuration in which a specified pixel 21 does not include the pixel separation portion 27 or the pixel separation portion 28 may be combined.

Further, when one pixel 21 includes the two photodiodes 41a and 41b as in the case of the imaging devices 11-3 to 11-3c, the volume of the photodiode 41 is reduced by half. This may also result in reducing the quantity of saturation signals by half. Thus, it is possible to prevent the reduction in the quantity of saturation signals by, for example, forming a fixed charge film or injecting impurities so as to increase the area of the P/N boundary (the area of a boundary between a p-type region and an n-type region).

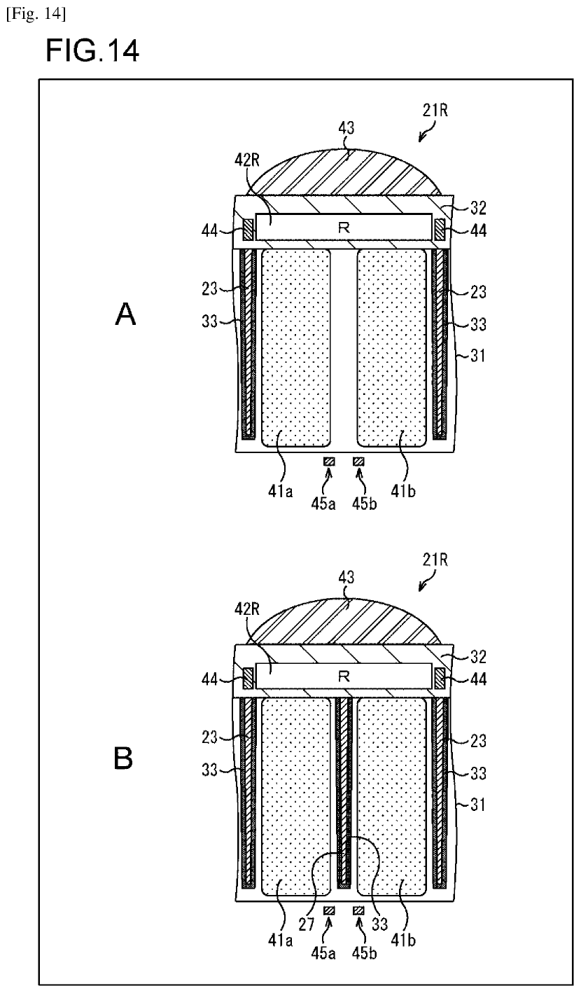

For example, FIGS. 14A and 14B illustrate configurative examples of providing a fixed charge film 33.

FIG. 14A illustrates a configuration in which one pixel 21R includes the two photodiodes 41a and 41b, as in the case of the imaging device 11-3 illustrated in FIG. 10. As illustrated in the figure, the fixed charge film 33 is formed on the side face of the pixel separation portion 23. Further, the fixed charge film 33 is also formed on the side face of the pixel separation portion 22, although this is not illustrated.

Further, FIG. 14B illustrates a configuration in which one pixel 21R includes the two photodiodes 41a and 41b and the two photodiodes 41a and 41b are separated from each other by the pixel separation portion 27. As illustrated in the figure, the fixed charge film 33 is formed on the side faces of the pixel separation portion 23 and the pixel separation portion 27. Further, the fixed charge film 33 is also formed on the side face of the pixel separation portion 22, although this is not illustrated. Note that, with respect to the imaging device 11-3b illustrated in FIG. 12 and the imaging device 11-3c illustrated in FIG. 13, a similar configuration can also be adopted.

As described above, the provision of the fixed charge film 33 enables the imaging devices 11-3 to 11-3c to increase the area of the P/N boundary and thus to prevent the reduction in the quantity of saturation signals of the photodiodes 41a and 41b. Thus, the imaging devices 11-3 to 11-3c make it possible to, for example, improve the performance in detecting a phase difference.

Method for Producing Imaging Device

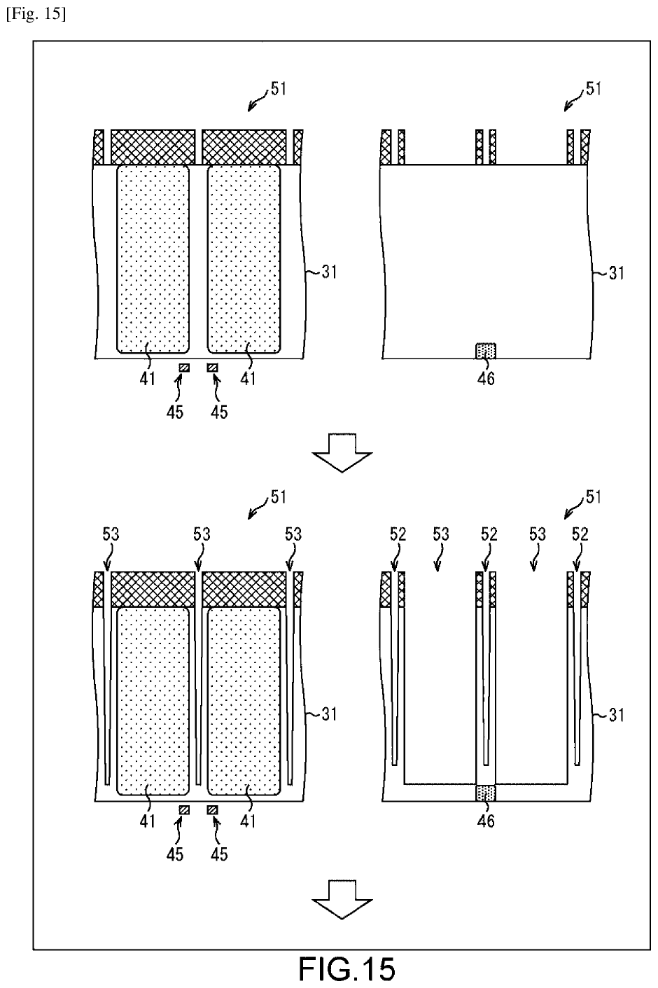

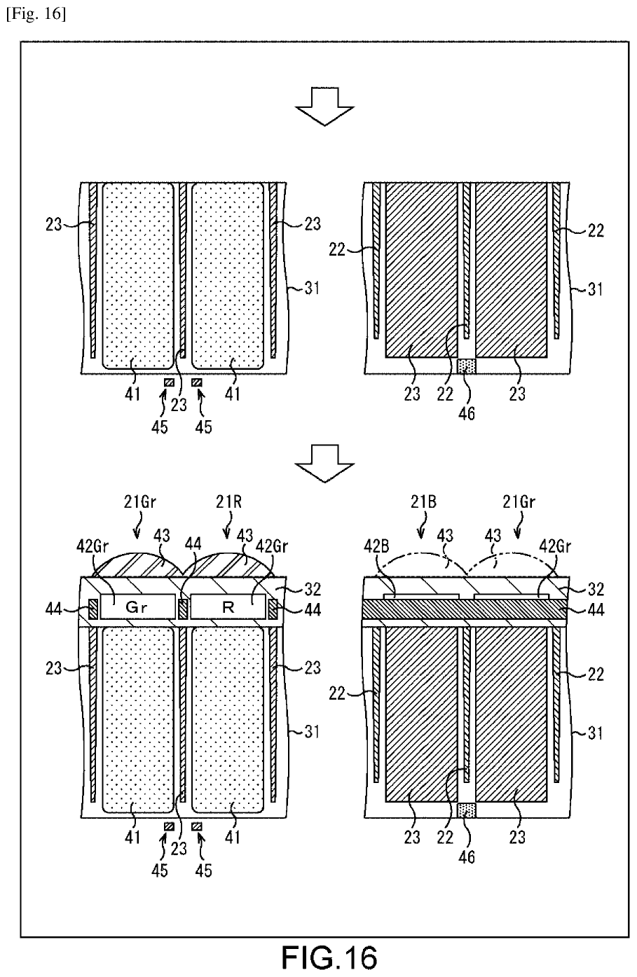

A method for producing the imaging device 11 is described with reference to FIGS. 15 and 16. FIGS. 15 and 16 each illustrate, on the left, the cross section taken along the dot-dash line A1-A1 of FIG. 1, and each illustrate, on the right, the cross section taken along the dot-dash line A2-A2 of FIG. 1.

First, as illustrated in the upper portion of FIG. 15, in a first process, the photodiode 41 and the FD section 46 are formed by injecting impurities into the semiconductor substrate 31. Further, the transistor 45 is formed on the element forming surface that is a front surface of the semiconductor substrate 31, a wire layer (not illustrated) is stacked on the element forming surface, and then a thin film is provided on the opposite surface of the semiconductor substrate 31 to form the light entrance surface. After that, the light entrance surface of the semiconductor substrate 31 is applied with a resist 51 and exposed to light, and an unnecessary portion is removed, so as to form the resist 51 covering a portion other than a portion in which the pixel separation portion 22 and the pixel separation portion 23 are formed.

Then, as illustrated in the lower portion of FIG. 15, in a second process, dry etching is performed on the semiconductor substrate 31 to engrave the portion, in the semiconductor substrate 31, that is not covered with the resist 51, so as to form trenches 52 and 53. Here, the resist 51 is formed such that the width of a trench in a portion corresponding to the pixel separation portion 23 is larger than the width of a trench in a portion corresponding to the pixel separation portion 22. Thus, due to the micro-loading effects, the trench 52 in the portion corresponding to the pixel separation portion 22 and the trench 53 in the portion corresponding to the pixel separation portion 23 are processed such that the trench 53 is deeper in depth than the trench 52. After that, the resist 51 is removed.

Next, in a third process, for example, an oxide film is embedded into the trenches 52 and 53 to form the pixel separation portion 22 and the pixel separation portion 23, as illustrated in the upper portion of FIG. 16. Note that the pixel separation portion 22 and the pixel separation portion 23 may be formed after the fixed charge film 33 illustrated in FIG. 14 is formed in the trenches 52 and 53.

Then, in a fourth process, a color filter 42 and an inter-pixel light shielding film 44 are arranged to form the insulation layer 32, and, further, patterning and processing are performed on the on-chip lens 43. Accordingly, as illustrated in the lower portion of FIG. 16, the imaging device 11 in which adjacent pixels 21 are separated from each other using the pixel separation portion 22 and the pixel separation portion 23 is produced.

In the production method described above, it is possible to simultaneously engrave the trenches 52 and 53 extending up to different depths by making the width of the trench 52 and the width of the trench 53 different from each other. This makes it possible to produce the imaging device 11 in a shorter time with a higher degree of processing accuracy.

Note that, for example, the trenches 52 and 53 may be separately engraved such that the trenches 52 and 53 have the same width and the etching times for the trenches 52 and 53 are different. For example, it is possible to form the pixel separation portion 23 to extend up to a deeper depth than that of the pixel separation portion 22 by making the etching time for the pixel separation portion 23 longer than the etching time for the pixel separation portion 22.

Here, when the trenches 52 and 53 are separately engraved, this may have a bad effect such as a decrease in processing accuracy in latter processing due to a difference in level that is caused in first processing. On the other hand, as described with reference to FIGS. 15 and 16, it is possible to prevent such a bad effect such as a difference in level from being caused by simultaneously engraving the trenches 52 and 53.

The imaging device 11 produced by the above-described processing makes it possible to improve the performance in pixel separation performed between the pixels 21 and to further improve an image quality, as described above.

Configurative Example of Electronic Apparatus

The imaging device 11 described above is applicable to various electronic apparatuses such as an image-capturing system such as a digital still camera and a digital video camera, a cellular phone including an image-capturing function, and other apparatuses including an image-capturing function.

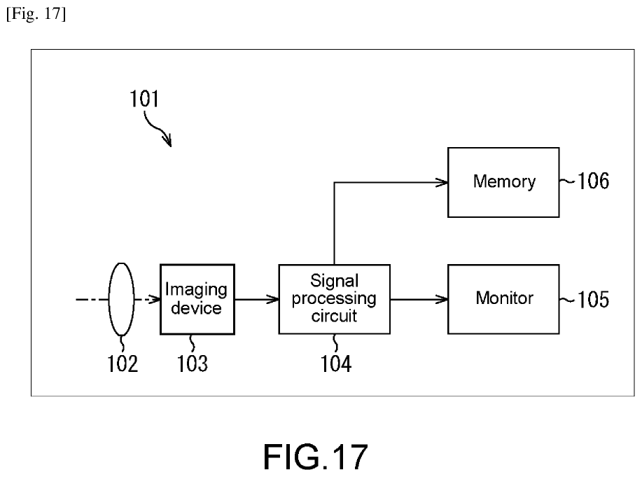

FIG. 17 is a block diagram illustrating a configurative example of an image-capturing apparatus that is mounted on an electronic apparatus.

As illustrated in FIG. 17, an image-capturing apparatus 101 includes an optical system 102, an imaging device 103, a signal processing circuit 104, a monitor 105, and a memory 106, and is capable of capturing a still image and a moving image.

The optical system 102 includes at least one lens, and guides image light (incident light) from a subject to the imaging device 103 to form an image on a light-reception surface (a sensor section) of the imaging device 103.

The imaging device 11 described above is used as the imaging device 103. Electrons are accumulated in the imaging device 103 for a certain period of time according to the image formed on the light-reception surface via the optical system 102. Then, a signal depending on the electron accumulated in the imaging device 103 is provided to the signal processing circuit 104.

The signal processing circuit 104 performs various signal processing on a pixel signal output from the imaging device 103. An image (image data) obtained by the signal processing circuit 104 performing signal processing is provided to the monitor 105 to be displayed on the monitor 105 and is provided to the memory 106 to be stored (recorded) in the memory 106.

For example, the image-capturing apparatus 101 having such a configuration can capture a higher-quality image by using the imaging device 11 described above.

Usage Example of Image Sensor

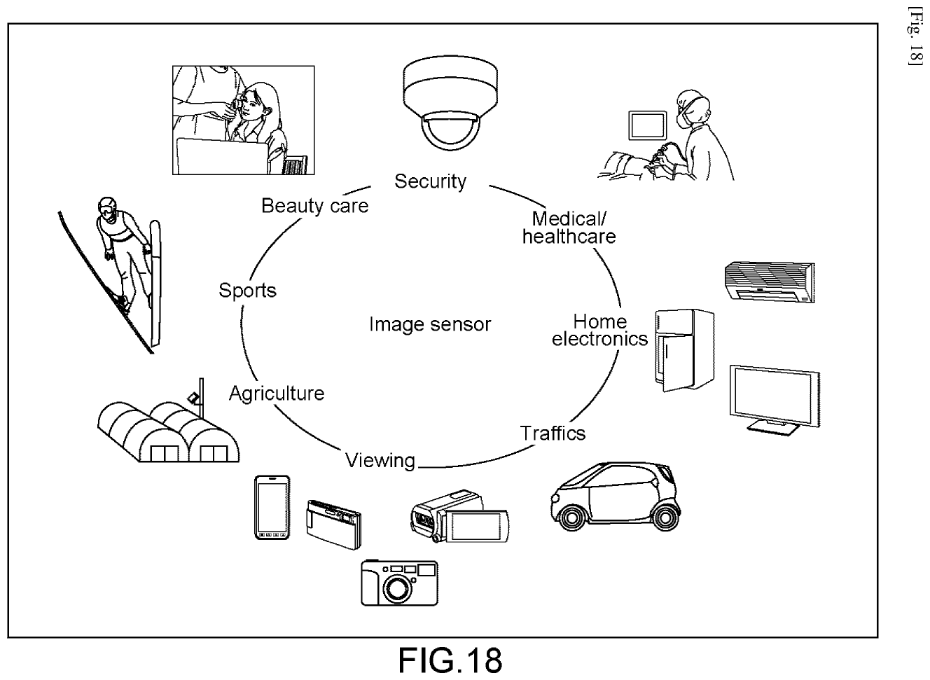

FIG. 18 illustrates a usage example of using an image sensor (the imaging device).

For example, as indicated below, the image sensor can be used in various cases of sensing light such as visible light, infrared light, ultraviolet light, and X-rays.
An apparatus that captures an image to be viewed, such as a digital camera and a camera-equipped mobile apparatus
An apparatus used for traffic purposes in order to, for example, ensure safe driving including automatic stop and recognize a driver's state; such as an in-vehicle sensor that captures images of the front/rear/periphery/inside of an automobile, a surveillance camera that monitors a running vehicle and a road, and a range sensor that measures a distance between vehicles
An apparatus used in home electronics in order to capture an image of a gesture of a user and to execute an apparatus operation according to the gesture; such as a TV, a refrigerator, and an air conditioner
An apparatus used for medical and healthcare purposes, such as an endoscope and an apparatus that captures an image of blood vessel by receiving infrared light
An apparatus used for security purposes, such as a surveillance camera for crime-prevention purposes and a camera for person authentication purposes
An apparatus used for beauty care purposes, such as a skin measurement apparatus that captures an image of skin and a microscope that captures an image of a scalp
An apparatus used for sports purposes, such as an action camera and a wearable camera for sports purposes
An apparatus used for agriculture purposes, such as a camera for monitoring a state of fields and crops

Example of Combination of Configurations

Note that the present technology may also take a configuration indicated below.

(1)

An imaging device including:

a photoelectric converter that is provided to a semiconductor substrate, the imaging device including a plurality of the photoelectric converters;

a separation portion that is provided between pixels each including the photoelectric converter, the separation portion extending up to a specified depth from a light entrance surface of the semiconductor substrate, the light entrance surface being on a side on which light enters the semiconductor substrate; and

an element that is provided on an element forming surface that is on a side opposite to the side of the light entrance surface, the imaging device including a plurality of the elements, in which

a first depth is deeper than a second depth, the first depth being a depth of the separation portion provided in a region in which the element is provided, the second depth being a depth of the separation portion provided in a region in which the element is not provided.

(2)

The imaging device according to (1), in which

a width of the separation portion extending up to the second depth is set to be smaller than a width of the separation portion extending up to the first depth.

(3)

The imaging device according to (1) or (2), in which

when the semiconductor substrate is viewed in a planar manner,

the separation portion extending up to the second depth is provided continuously with respect to a plurality of the photoelectric converters in a specified direction,

the separation portion extending up to the first depth is provided for each photoelectric converter in a direction orthogonal to the specified direction, and

a space is provided that makes the separation portion extending up to the first depth and the separation portion extending up to the second depth discontinuous.

(4)

The imaging device according to any one of (1) to (3), in which

the separation portion extending up to the first depth and the separation portion extending up to the second depth are provided by simultaneously engraving the respective separation portions in a state in which a width of the separation portion extending up to the second depth is smaller than a width of the separation portion extending up to the first depth.

(5)

The imaging device according to (3), in which

the separation portion extending up to the first depth and the separation portion extending up to the second depth are provided by separately engraving the respective separation portions.

(6)

The imaging device according to (3), in which

the separation portion extending up to the first depth is arranged at a position adjusted according to an image height of a position at which the photoelectric converter is arranged.

(7)

The imaging device according to (1), in which

when the semiconductor substrate is viewed in a planar manner, the separation portion is formed to surround each of the plurality of the photoelectric converters.

(8)

The imaging device according to any one of (1) to (7), in which

a specified number of the photoelectric converters is provided with respect to a single pixel.

(9)

The imaging device according to (8), in which

the separation portion extending up to the first depth is provided between the photo-electric converters in the single pixel.

(10)

The imaging device according to (8) or (9), in which

the separation portion is provided in a region other than a center portion in the pixel.

(11)

The imaging device according to any one of (8) to (10), in which

a boundary between a p-type region and an n-type region is provided on a sidewall of the separation portion.

(12)

A method for producing an imaging device, the method including:

forming a photoelectric converter on a semiconductor substrate, in which a plurality of the photoelectric converters is formed on the semiconductor substrate;

forming a separation portion between pixels each including the photoelectric converter, the separation portion extending up to a specified depth from a light entrance surface of the semiconductor substrate, the light entrance surface being on a side on which light enters the semiconductor substrate; and

forming an element on an element forming surface that is on a side opposite to the side of the light entrance surface, in which a plurality of the elements is formed on the element forming surface, in which

a first depth is deeper than a second depth, the first depth being a depth of the separation portion provided in a region in which the element is provided, the second depth being a depth of the separation portion provided in a region in which the element is not provided.

(13)

An electronic apparatus including an imaging device that includes

a photoelectric converter that is provided to a semiconductor substrate, the imaging device including a plurality of the photoelectric converters;

a separation portion that is provided between pixels each including the photoelectric converter, the separation portion extending up to a specified depth from a light entrance surface of the semiconductor substrate, the light entrance surface being on a side on which light enters the semiconductor substrate; and

an element that is provided on an element forming surface that is on a side opposite to the side of the light entrance surface, the imaging device including a plurality of the elements, in which

a first depth is deeper than a second depth, the first depth being a depth of the separation portion provided in a region in which the element is provided, the second depth being a depth of the separation portion provided in a region in which the element is not provided.

Note that the present embodiment is not limited to the examples described above, and various modifications may be made thereto without departing from the spirit of the present disclosure. Further, the effects described herein are not limitative but merely illustrative, and other effects may be provided.

### REFERENCE SIGNS LIST

11 Imaging device

21 Pixel

22 to 24 Pixel separation portion

25, 26 Wide portion

27, 28 Pixel separation portion

31 Semiconductor substrate

32 Insulation layer

33 Fixed charge film

41 Photodiode

42 Color filter

43 On-chip lens

44 Inter-pixel light shielding film

45 Transistor

46 FD section

51 Resist

52, 53 Trench

What is claimed is:

1. An imaging device, comprising:
a photoelectric converter that is provided to a semiconductor substrate, the imaging device comprising a plurality of the photoelectric converters;
a separation portion that is provided between pixels each including the photoelectric converter, the separation portion extending up to a specified depth from a light entrance surface of the semiconductor substrate, the light entrance surface being on a side on which light enters the semiconductor substrate; and
an element that is provided on an element forming surface that is on a side opposite to the side of the light entrance surface, the imaging device comprising a plurality of the elements, wherein
a first depth is deeper than a second depth, the first depth being a depth of the separation portion provided in a region in which the element is provided, the second depth being a depth of the separation portion provided in a region in which the element is not provided.

2. The imaging device according to claim 1, wherein
a width of the separation portion extending up to the second depth is set to be smaller than a width of the separation portion extending up to the first depth.

3. The imaging device according to claim 1, wherein
when the semiconductor substrate is viewed in a planar manner,
the separation portion extending up to the second depth is provided continuously with respect to a plurality of the photoelectric converters in a specified direction,
the separation portion extending up to the first depth is provided for each photoelectric converter in a direction orthogonal to the specified direction, and
a space is provided that makes the separation portion extending up to the first depth and the separation portion extending up to the second depth discontinuous.

4. The imaging device according to claim 3, wherein
the separation portion extending up to the first depth and the separation portion extending up to the second depth are provided by simultaneously engraving the respective separation portions in a state in which a width of the separation portion extending up to the second depth is smaller than a width of the separation portion extending up to the first depth.

5. The imaging device according to claim 3, wherein
the separation portion extending up to the first depth and the separation portion extending up to the second depth are provided by separately engraving the respective separation portions.

6. The imaging device according to claim 3, wherein
the separation portion extending up to the first depth is arranged at a position adjusted according to an image height of a position at which the photoelectric converter is arranged.

7. The imaging device according to claim 1, wherein
when the semiconductor substrate is viewed in a planar manner, the separation portion is formed to surround each of the plurality of the photoelectric converters.

8. The imaging device according to claim 1, wherein
a specified number of the photoelectric converters is provided with respect to a single pixel.

9. The imaging device according to claim 8, wherein
the separation portion extending up to the first depth is provided between the photoelectric converters in the single pixel.

10. The imaging device according to claim 9, wherein
the separation portion is provided in a region other than a center portion in the pixel.

11. The imaging device according to claim 8, wherein
a boundary between a p-type region and an n-type region is provided on a sidewall of the separation portion.

12. A method for producing an imaging device, the method comprising:
forming a photoelectric converter on a semiconductor substrate, in which a plurality of the photoelectric converters is formed on the semiconductor substrate;
forming a separation portion between pixels each including the photoelectric converter, the separation portion extending up to a specified depth from a light entrance surface of the semiconductor substrate, the light entrance surface being on a side on which light enters the semiconductor substrate; and
forming an element on an element forming surface that is on a side opposite to the side of the light entrance surface, in which a plurality of the elements is formed on the element forming surface, wherein
a first depth is deeper than a second depth, the first depth being a depth of the separation portion provided in a region in which the element is provided, the second depth being a depth of the separation portion provided in a region in which the element is not provided.

13. An electronic apparatus comprising an imaging device that includes
a photoelectric converter that is provided to a semiconductor substrate, the imaging device including a plurality of the photoelectric converters;
a separation portion that is provided between pixels each including the photoelectric converter, the separation portion extending up to a specified depth from a light entrance surface of the semiconductor substrate, the light entrance surface being on a side on which light enters the semiconductor substrate; and
an element that is provided on an element forming surface that is on a side opposite to the side of the light entrance surface, the imaging device including a plurality of the elements, wherein
a first depth is deeper than a second depth, the first depth being a depth of the separation portion provided in a region in which the element is provided, the second depth being a depth of the separation portion provided in a region in which the element is not provided.
